(19) United States
(12) Patent Application Publication
(10) Pub. No.: US 2007/0277215 A1
(43) Pub. Date: Nov. 29, 2007

(54) CONTACT LIST FOR A HYBRID COMMUNICATOR/REMOTE CONTROL

(75) Inventors: Paul G. Allen, Mercer Island, WA (US); James A. Billmaier, Woodinville, WA (US); Robert E. Novak, Kirkland, WA (US)

Correspondence Address: DIGEO, INC C/O STOEL RIVES LLP, 201 SOUTH MAIN STREET, SUITE 1100, ONE UTAH CENTER, SALT LAKE CITY, UT, 84111, US

(73) Assignee: Digeo, Inc., Kirkland, WA (US)

(21) Appl. No.: 11/835,848

(22) Filed: Aug. 8, 2007

Related U.S. Application Data
(63) Continuation of application No. 09/863,053, filed on May 22, 2001.
(60) Provisional application No. 60/283,525, filed on Apr. 12, 2001.
(60) Provisional application No. 60/285,086, filed on Apr. 19, 2001.

(51) Int. Cl. H04N 7/173; G10L 21/00; H03M 1/20

(52) U.S. Cl. 725/131; 341/176; 704/275

(57) ABSTRACT

A hybrid communicator/remote control includes an integrated display screen configured to display a contact list. Each contact in the contact list includes an address, such as a network address, for establishing two-way communication with the contact. Moreover, each contact in the contact list includes a visual identifier, such as a name, picture, or the like, that identifies the contact. A user may select a contact from the contact list, after which a communication channel is established between the hybrid communicator/remote control and a device used by the selected contact, such as a telephone, Internet-accessible telephone, or another hybrid communicator/remote control.

### RELATED APPLICATIONS

This application is a continuation of U.S. patent application Ser. No. 09/863,053, filed May 22, 2001, for “Contact List for a Hybrid Communicator/Remote Control,” with inventors Paul G. Allen, James A. Billmaier, and Robert E. Novak. U.S. patent application Ser. No. 09/863,053 is related to and claims priority from U.S. Patent Application Ser. No. 60/283,525, filed Apr. 12, 2001, for “Contact List for a Hybrid Communicator/Remote Control,” with inventors Paul G. Allen and James A. Billmaier. U.S. patent application Ser. No. 09/863,053 is also related to and claims priority from U.S. Patent Application Ser. No. 60/285,086, filed Apr. 19, 2001, for “Multifunction Display Screen for a Hybrid Communicator/Remote Control,” with inventors James A. Billmaier, Jeffrey C. Pandolfo, Korina J. Brown, Anthony I. Istvan, Jeffrey C. McMillen, Michael E. Sears, Jonathan D. Broadus, and Paul G. Allen. Each of the above-referenced applications are commonly assigned and are hereby incorporated by reference herein in their entirety.

### FIELD OF THE INVENTION

The present invention relates generally to the field of interactive television systems. More specifically, the present invention relates to a system and method for providing a contact list for a hybrid communicator/remote control within an interactive television system.

### DESCRIPTION OF RELATED BACKGROUND ART

Television watching is an immensely popular pastime throughout the world. Indeed, one or more televisions can be found in virtually every residence in the United States and many foreign countries. The television viewing area is often the focal point of the home, a location at which family members spend a considerable amount of time, even when not watching television.

Unfortunately, telephones and telephone directories are often located outside of the television viewing area. As a result, a person must often leave the proximity of the television to make or receive telephone calls. If the caller is watching a television program, he or she may miss a significant portion of the program by the time a telephone call has been placed or answered. This is particularly irksome if the caller wishes to discuss an ongoing television program with another individual over the telephone. Moreover, a caller is often thwarted by others in the household who need the household telephone line for telephonic or Internet use.

If the caller does not know the telephone number of a person he or she wishes to contact, the caller must conventionally search voluminous telephone directories, scraps of paper, planners, personal desktop assistants (PDA's), and the like, for the number. This further reduces the caller's time for watching the television and diminishes the television viewing experience.

In some cases, either the caller or the intended recipient of the call may not have access to a conventional telephone line. For example, many people are now using the Internet for telephonic communication. Typically, Internet-accessible telephonic connections do not operate with the same protocols as standard telephone numbers. For example, an Internet-based telephone may use an IP (Internet Protocol) address instead of a telephone number. The caller, therefore, may need to remember a somewhat complicated, strangely formatted address in order to make contact with a party using an Internet-based telephone.

Consequently, it would be an advancement in the art to provide a system and method by which a person could communicate remotely with another party without leaving the television viewing area, either to access a telephone or to look up a telephone number. Such a system and method should be independent of the location of the household telephone and should not depend on the household's telephone line. Furthermore, it would be an advancement in the art to provide a system and method by which the person could rapidly and easily place a telephone call to a wide variety of devices, including wireless and Internet-based devices.

### BRIEF DESCRIPTION OF THE DRAWINGS

Non-exhaustive embodiments of the invention are described with reference to the figures, in which:

FIG. 1 is a schematic block diagram of a system for providing television programming and communication services;

FIG. 2 is an illustration of a hybrid communicator/remote control in the context of an interactive television system;

FIG. 3 is a schematic block diagram of physical components of a set top box;

FIG. 4 is a schematic block diagram of physical components of a remote control;

FIG. 5 is a schematic block diagram of logical components of a system for providing two-way communication using a hybrid communicator/remote control;

FIG. 6 is an illustration of hybrid communicator/remote control displaying a graphical image of a contact's face;

FIG. 7 is an illustration of an alternative embodiment of an interactive television system including a microphone and speaker integrated with a set top box;

FIG. 8 is a flowchart of a method for creating and using a contact list within a hybrid communicator/remote control;

FIG. 9 is a schematic block diagram of logical components of a system for canceling noise, including TV audio output, from captured audio input; and

FIG. 10 is a schematic block diagram of logical components of a system for suppressing TV audio output during capture of audio input.

### DETAILED DESCRIPTION OF THE PREFERRED EMBODIMENTS

The present invention solves the foregoing problems and disadvantages with a system and method for providing a contact list for a hybrid communicator/remote control. The hybrid communicator/remote control preferably allows a user to remotely operate an interactive television system, including, for example, a set top box and an attached television set.

In one embodiment, the hybrid communicator/remote control also facilitates two-way communication between a user and a remote party by including an integrated speaker and microphone. In certain embodiments, the speaker and microphone may be attached externally to the remote control (e.g., within a headset), or may be integrated with a set top box for the interactive television system. Optionally, the hybrid communicator/remote control may also include a digital video camera for videoconferencing.

The hybrid communicator/remote control also preferably includes a display screen, such as an integrated LCD screen, for displaying a contact list. The contact list identifies one or more individuals with whom the user frequently communicates, as well as an address for each contact. The address may be a conventional telephone address, an address of another interactive television system, an address of an Internet-accessible phone, or the like. The contacts may be identified in the contact list by a name, a picture, or other similar identifier.

A user may select a contact from the list in order to establish a two-way communication channel with the contact. This may be accomplished, in various embodiments, using buttons or other controls integrated with the hybrid communicator/remote control. For example, a user may employ up and down arrows to highlight a desired contact (by name, picture, etc.) within the contact list, after which the user may press a “Call” button or the like. Alternatively, a digitized verbal identifier may also be stored for one or more contacts to facilitate voice-activated selection of a contact.

Preferably, the system and method includes several different mechanisms by which the user can enter new contacts into the contact list. In certain embodiments, new contacts may be manually entered by means of buttons or the like on the hybrid communicator/remote control. Alternatively, new contacts may be selected from a list displayed on either the television or the integrated display screen of the hybrid communicator/remote control. In another embodiment, new contacts may be automatically entered when a user communicates with a party via the hybrid communicator/remote control. In still another embodiment, a list of one or more contacts may be received from external device in communication with the hybrid communicator/remote control, such as a PDA, a cellular phone, or another hybrid communicator/remote control.

As used herein, the term “contact” refers to a person to whom a caller may wish to communicate. A “contact list” refers to stored data relating to one or more contacts. An “address” identifies or locates a device capable of telephonic communication, such as a telephone, an interactive television system (including the described hybrid communicator/remote control), a wireless communication device (e.g., cellular phone), a computer including hardware and software for Internet-based telephony, or the like. Thus, the term “address” contemplates various types of network addresses, such as telephone numbers, IP addresses, URLs (Universal Resource Locators), MAC (Media Access Control) addresses, and the like. The term “visual identifier” may refer to any visual indication of the identity of a contact, including text, pictures, symbols, and the like.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

Furthermore, the described features, structures, or characteristics may be combined in any suitable manner in one or more embodiments. In the following description, numerous specific details are provided, such as examples of programming, user selections, network transactions, database queries, database structures, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Throughout the following disclosure, the term “coupled” may be used to refer to components that are either directly connected or linked by one or more other components. Thus, as used herein, the term “coupled” may be synonymous with “in electrical communication with” or simply “in communication with.”

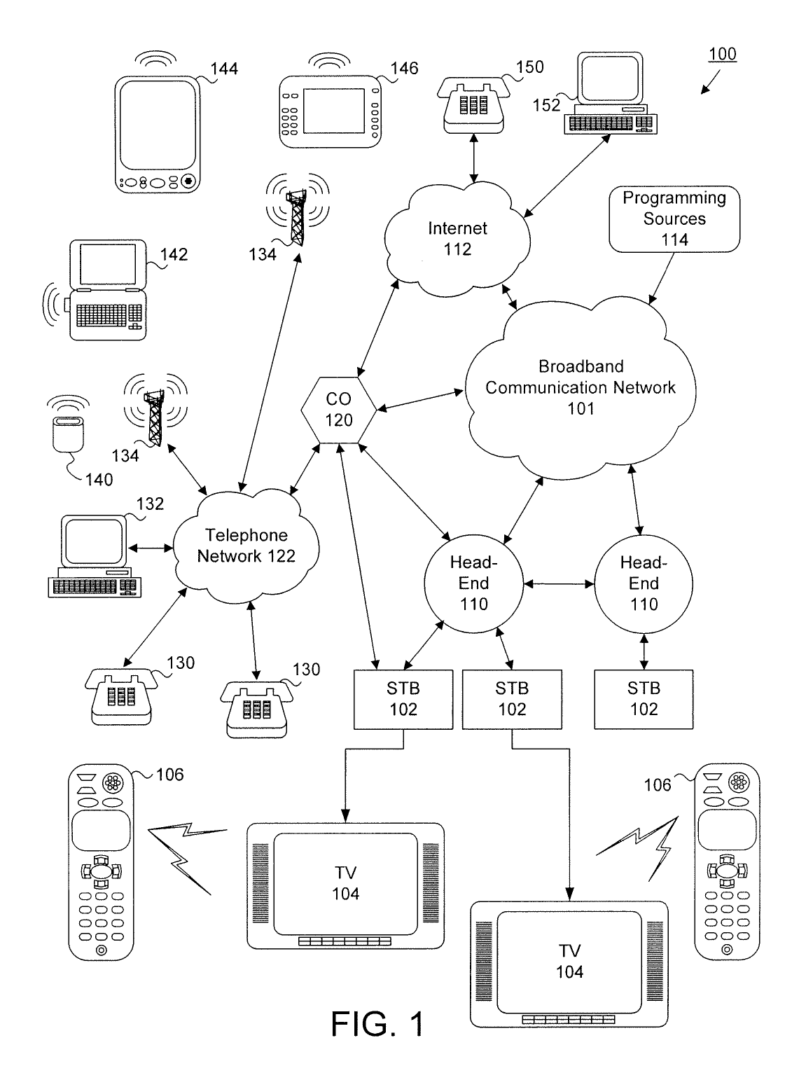

Referring now to FIG. 1, there is shown a system 100 for providing television programming and communication services to a plurality of customers. In one implementation, the system 100 is based on the infrastructure of broadband communication network 101, such as a cable network. However, other networks are contemplated, one particular example of which is a satellite network.

In one configuration, the system 100 includes a plurality of set top boxes (STBS) 102 located, for instance, at customer homes. Generally, an STB 102 is a consumer electronics device that serves as a gateway between a customer's television 104 and the network 101. In alternative embodiments, an STB 102 may be embodied more generally as a personal computer (PC), an advanced television 104 with built-in STB functionality, or another type of client terminal.

An STB 102 receives encoded television signals and other information from the network 101 and decodes the same for display on the television 104 or other display device, such as a computer monitor, projection screen television, high-definition (HD) television, flat panel display, or the like. As its name implies, an STB 102 is typically located on top of, or in close proximity to, the television 104.

Each STB 102 may be distinguished from other network components by a unique identifier, number, code, or address, examples of which include an IP (Internet Protocol) address or a MAC (Media Access Control) address. Thus, video streams and other information may be transmitted from the network 101 to a specific STB 102 by specifying the corresponding address, after which the network 101 routes the transmission to its destination using conventional techniques.

As described more fully below, a hybrid communicator/remote control 106 is provided, in one configuration, for convenient remote operation of the STB 102 and the television 104. The hybrid communicator/remote control 106 may use infrared (IR), radio frequency (RF), or other wireless technologies to transmit control signals to the STB 102 and the television 104. Other remote control devices are also contemplated, such as a wired or wireless mice (not shown), PDAs, webpads, etc.

In one embodiment, each STB 102 is coupled to a head-end 110 or other distribution node of the network 101. In the context of a cable network, a head-end 110 is generally a centrally-located facility within a community where television programming is received from a satellite downlink or other source and packaged together for transmission to customer homes. In one configuration, a head-end 110 also functions as a Central Office (CO) in the telephone industry, routing data streams to and from the various STBs 102 serviced thereby. Head-ends 110 may be coupled directly to one another or through the network 101. In alternative embodiments, head-ends 110 may be connected via a separate network, one particular example of which is the Internet 112.

The network 101 is preferably coupled to one or more television programming sources 114, which provide television programming for distribution to the STBs 102. In one configuration, television programs are distributed in an encoded format, such as MPEG (Moving Picture Experts Group). Various MPEG formats are known, such as MPEG-2, MPEG-4, MPEG-7, and the like. Thus, the term “MPEG,” as used herein, contemplates all MPEG formats. Moreover, other video encoding/compression standards exist other than MPEG, such as JPEG, JPEG-LS, H.261, and H.263. Accordingly, the invention should not be construed as being limited only to MPEG.

The network 101 is also preferably coupled to the Internet 112 to provide access thereto by the STBs 102. The Internet 112 is a “network of networks” and is well known to those skilled in the art. Communication over the Internet 112 is accomplished using standard protocols, such as TCP/IP (Transmission Control Protocol/Internet protocol) and the like.

As explained in greater detail below, the hybrid communicator/remote control 106 and/or the STB 102 may be equipped with a microphone and/or speaker to provide telephonic communication with one or more other parties. Video communication may also be carried out by, for example, providing a video camera within the hybrid communicator/remote control 106 and/or STB 102.

A Central Office (CO) 120 for a telephone network 122 may be connected to any or all of the STBs 102, the head-ends 110, the broadband communication network 101, and the Internet 112. Multiple COs 120, and indeed, multiple telephone networks 122, may be connected to the STBs 102, head-ends 110, the broadband communication network 101, or the Internet 112.

The telephone network 122 may be embodied as a conventional packet switched telephone network (PSTN), as known in the art. Standard telephones 130 may be connected to the telephone network 122 via telephone lines. Additionally, desktop computers 132 with appropriate telephony circuitry may also be connected to the telephone network 122.

The telephone network 122 may be connected to a plurality of wireless devices via wireless transmitters 134 (such as cellular antennas). The wireless transmitters 134 may be in communication with various types of wireless devices, such as pagers 140, laptops 142, PDAs 144, and webpads 146.

Furthermore, some devices may be connected to the Internet 112 independent of the telephone network 122. For example, an Internet-accessible telephone 150, or “webphone,” may be coupled via a high-speed connection (e.g., cable, DSL) to the Internet 112. Additionally, a computer 152 may be coupled to the Internet 112 by a similar connection.

The present invention provides a system and method by which a user of a hybrid communicator/remote control 106 may rapidly and easily establish a two-way communication channel with any of the illustrated devices 106, 130, 132, 140, 142, 144, 146, 150, 152. Of course, the system 100 illustrated in FIG. 1 is merely exemplary, and other types of devices and networks may be used within the scope of the invention.

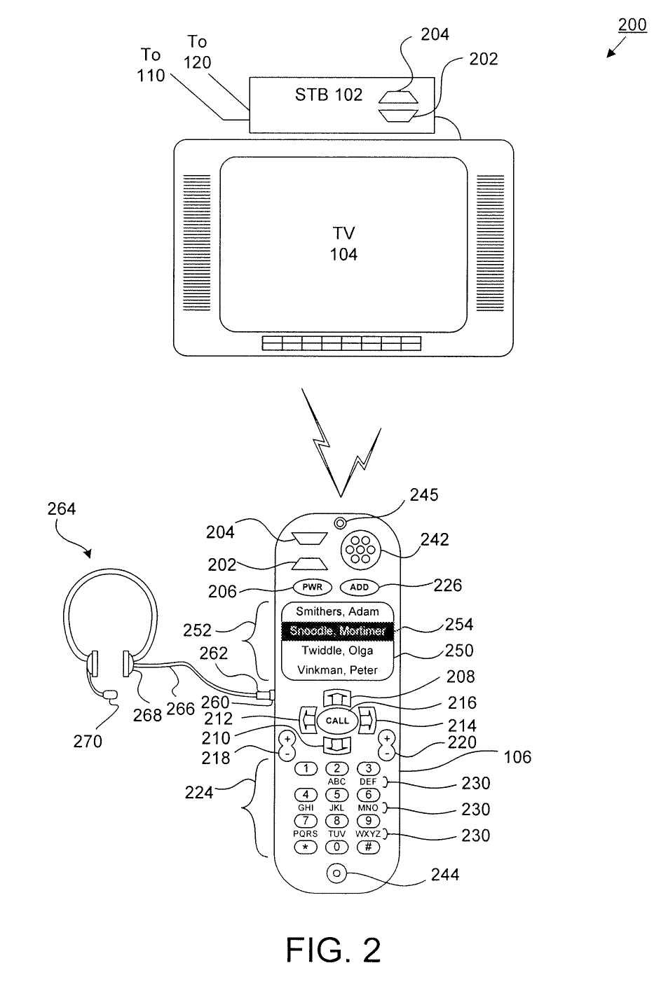

Referring now to FIG. 2, there is shown an interactive television system 200 according to an embodiment of the invention. As depicted, the system 200 may include an STB 102, a television 104 (or other display device), and a hybrid communicator/remote control 106.

The hybrid communicator/remote control 106 is provided for convenient remote operation of the STB 102 and the television 104. In one configuration, the hybrid communicator/remote control 106 includes a wireless transmitter 202 for communicating with a corresponding wireless receiver 204 within the STB 102. Likewise, the hybrid communicator/remote control 106 includes a wireless receiver 204 for receiving signals from a wireless transmitter 202 within the STB 102.

In one embodiment, the wireless transmitters 202 and receivers 204 are configured to use radio frequency (RF) signals. In other embodiments, infrared (IR) or other frequencies along the electromagnetic spectrum may be used.

The hybrid communicator/remote control 106 preferably includes a number of buttons or other similar controls for receiving user commands. For instance, the hybrid communicator/remote control 106 may include a power button 206, an up arrow button 208, a down arrow button 210, a left arrow button 212, a right arrow button 214, a “Call” button 216, channel buttons 218, volume buttons 220, alphanumeric buttons 224, and an “Add” button 226. Each of the alphanumeric buttons 224 may be associated with a set of alphabet characters 230 for entering text into the hybrid communicator/remote control 106 without an external keyboard. Various buttons and controls may have dedicated functions, while other buttons and controls may have multiple functions. The operation of certain of the above-described buttons and controls will be discussed in greater detail below.

As depicted in FIG. 2, the hybrid communicator/remote control 106 may include a speaker 242 for generating an audible output from an audio signal received through the wireless receiver 204. In addition, the hybrid communicator/remote control 106 may include a microphone 244 for capturing an audio signal, which may be transmitted to the STB 102 by the wireless transmitter 202. In certain embodiments, the hybrid communicator/remote control 106 may also include a digital video camera 245, such as a standard CCD digital video camera, for capturing a video signal for transmission to the STB 102.

The various components of the hybrid communicator/remote control 106 may be positioned in different locations for functionality and ergonomics. For example, as shown in FIG. 2, the speaker 242 may be positioned near the “top” of the hybrid communicator/remote control 106 (when viewed from the perspective of FIG. 2) and the microphone 244 may be positioned at the “bottom” of the hybrid communicator/remote control 106. Thus, in one embodiment, a user may conveniently position the speaker 242 near the user's ear and the microphone 244 near the user's mouth in order to operate the hybrid communicator/remote control 106 in the manner of a telephone.

In alternative embodiments, the speaker 242 and the microphone 244 may be integrated with the STB 102 and/or the television 104. Alternatively or in addition, the hybrid communicator/remote control 106 may include a headset jack 260 configured to receive a standard headset plug 262 or the like. The headphone plug 262 may be connected to a hands-free headset 264 by a wire 266. The headset 264 may, for example, include one or two earphones 268 and a microphone 270 mounted on a boom or other similar apparatus designed to position the microphone 270 near the user's mouth. Such a headset 264 may be used to reduce audio interference from the television 104 (improving audio quality) and to provide the convenience of hands-free operation.

In one implementation, the wireless transmitter 202 of the hybrid communicator/remote control 106 is in electrical communication with the microphone 244 and/or video camera 245 to receive a captured audio/video signal. The transmitter 202 preferably modulates the captured signal with a carrier frequency to enable transmission thereof to the STB 102 using techniques well known in the art. For example, the wireless transmitter 202 may operate according to the IEEE 802.11a or 802.11b Wireless Networking standards, the “Bluetooth” standard, or according to other standard or proprietary wireless techniques. Modulation techniques may include spread spectrum, frequency shift keying, multiple carrier, or other techniques known in the art.

To achieve modulation and transmission, the wireless transmitter 202 may include various additional components not specifically illustrated but well known in the art. For example, the wireless transmitter 202 may include a source encoder for bandwidth reduction, a channel encoder for modulating the captured signal with a carrier signal, an amplifier, and a non-directional transmission antenna. The antenna may comprise a substantially two-dimensional metal structure formed on a printed circuit board for the hybrid communicator/remote control 106.

Likewise, the wireless receiver 204 of the hybrid communicator/remote control 106 may further include components not specifically illustrated but well known in the art. For example, the wireless receiver 204 may include an antenna for receiving a signal from the STB 102, an amplifier for increasing the strength of the received signal, and a decoder for separating and demodulating data from the carrier signal.

In one embodiment, the wireless transmitter 202 and the wireless receiver 204 are configured to send and receive digitally-encoded signals. As such, the wireless transmitter 202 may include an analog-to-digital converter (ADC) for converting analog audio signals into digital signals. Likewise, the wireless receiver 204 may include a digital-to-analog converter (DAC) to convert digital signals into analog signals. The present invention contemplates the use of either or both of analog and digital transmissions to and from the hybrid communicator/remote control 106.

In the illustrated embodiment, the STB 102 includes a wireless receiver 204 (similar to the one in the hybrid communicator/remote control 106) for receiving commands and audio/video signals from the hybrid communicator/remote control 106. Similarly, the STB 102 may include a wireless transmitter 202 (similar to the one in the hybrid communicator/remote control 106) for sending audio/video signals and other data to the wireless receiver 204 in the hybrid communicator/remote control 106.

The hybrid communicator/remote control 106 also preferably includes a display screen 250. The display screen 250 may be in electrical communication with the wireless receiver 204 to display a video signal received from the STB 102 during videoconferencing.

The display screen 250 may be of any suitable type, but is preferably a liquid crystal display (LCD). If desired, the display screen 250 may be a backlit for enhanced picture quality and viewing in a dark environment. Additionally, the display screen 250 may be color or monochromatic in various embodiments.

The display screen 250 is also preferably configured to display a contact list 252. In one embodiment, the contact list 252 includes one or more visual identifiers 254 of people with whom the user may communicate using the hybrid communicator/remote control 106. As depicted, the visual identifier 254 may be a name of the contact. Alternatively, as described in detail below, the visual identifier 254 include a contact's picture, a symbol (e.g., icon), or the like.

The contact list 252 may be entirely stored within the hybrid communicator/remote control 106. Alternatively, a user may “scroll” through a larger contact list 252 stored within the STB 102, with only a portion of the list 252 being retrieved and displayed by the hybrid communicator/remote control 106.

The hybrid communicator/remote control 106 preferably includes a mechanism by which a visual identifier 254 of a contact from the contact list 252 may be selected by a user. For example, using the up and down arrow buttons 208, 210, a user may highlight or otherwise mark a visual identifier 254 of a desired contact, e.g., “Snoodle, Mortimer” in FIG. 2.

Thereafter, as described in greater detail below, the user may be placed in communication with that individual by pressing the “Call” button 216 or the like. In certain embodiments, the user may also terminate a call by pressing the “Call” button 216.

The contact list 252 may also be displayed on the television 104 in a similar fashion. If desired, contact list 252 may be displayed on the television 104 in addition to, or in lieu of, a similar display on the display screen 250 integrated with the hybrid communicator/remote control 106.

The “Add” button 226 is used, in one embodiment, to add new contacts to the contact list 252. As described in detail below, the user may press the “Add” button 226 to enter an manual entry mode in which the alphanumeric buttons 224 may be pressed to enter a name and associated address for a new contact. As described previously, the address may be a telephone number, a network address for another interactive television system 200, an Internet address, or the like. The user may then press the “Add” button 226 to complete the addition of the new contact to the contact list 252.

In alternative embodiments, the “Add” button 226 may be used to enter a contact selection mode in which the user may select a contact from a list (not shown), which may be retrieved from a remote telephone directory or contact list via the broadband communication network 101 or the Internet 112. For example, in response to activation of the “Add” button 226, a directory or contact list may be retrieved from the network 101 (via the STB 102) and displayed on the television 104 or display screen 250. Using the arrow buttons 208, 210, 212, 214, the user may highlight or otherwise mark a contact and press the “Add” button 226, after which information for the contact is added to the contact list 252 of the hybrid communicator/remote control 106.

Alternatively, the display screen 250 and/or television 104 may display a calling history including a list of contacts with whom the user has communicated via the hybrid communicator/remote control 106. In one embodiment, a user may select a contact from the calling history to add to the contact list 252 of the hybrid communicator/remote control 106 using the arrow buttons 208, 210, 212, 214 and the “Add” button 226. The telephone number or other address of the contact may be obtained by a caller identification (“Caller ID”) feature of the telephone network 122 or an equivalent feature within an Internet-based telephone system.

In yet another embodiment, the hybrid communicator/remote control 106 may be configured to link electronically with an external electronic device to receive new contacts for the contact list 252. For example, the hybrid communicator/remote control 106 may be placed in communication with a PDA, a cellular telephone, a computer, or another hybrid communicator/remote control 106 to receive one or more contacts, including the contact's address and visual identifier 254 (e.g., name, picture, etc.). The communication may be accomplished using the wireless transmitter 202 and receiver 204 of the hybrid communicator/remote control 106.

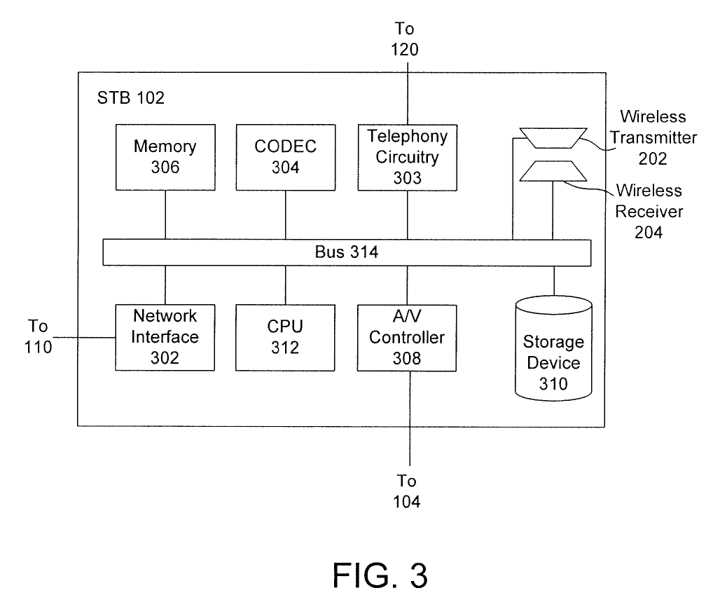

Referring now to FIG. 3, there is shown a physical block diagram of an STB 102 according to an embodiment of the invention. As noted above, the STB 102 includes a wireless receiver 204 for receiving control signals and audio/video signals from the wireless transmitter 202 in the hybrid communicator/remote control 106. Additionally, the STB 102 includes a wireless transmitter 202 for transmitting audio/video signals to the hybrid communicator/remote control 106.

The STB 102 also includes, in one implementation, a network interface 302 for communicating with the broadband communication network 101 via the head-end 110. The interface 302 may include conventional tuning, demodulating, and demultiplexing circuitry for receiving MPEG (Moving Picture Experts Group) packets corresponding to a selected MPEG channel. The interface 302 may also include conventional cable modem circuitry for sending or receiving other types of data. For example, the interface 302 may conform to the DOCSIS (Data Over Cable Service Interface Specification) or DAVIC (Digital Audio-Visual Council) cable modem standards. In one embodiment, a CMTS-DRFI (Cable Modem Termination System-Downstream RF Interface) may be used in conjunction with a CMTS-URFI (Cable Modem Termination System-Downstream RF Interface) to establish two-way communication between the STB 102 and the head-end 110.

In one configuration, one or more frequency bands (for example, from 5 to 30 MHz) may be reserved for upstream transmission. Digital modulation (for example, quadrature amplitude modulation or vestigial sideband modulation) may be used to send digital signals in the upstream transmission. Of course, upstream transmission may be accomplished differently for different networks 101. Alternative ways to accomplish upstream transmission include using a back channel transmission, which is typically sent via an analog telephone line, ISDN, DSL, or other techniques.

In an embodiment in which the STB 102 is connected directly to the CO 120, the STB 102 includes standard telephony circuitry 303. The telephony circuitry 303 may be used to dial a telephone number and establish a two-way telephone connection between the STB 102 and a device 130, 132, 140, 142, 144, 146 connected to the telephone network 122.

In one embodiment, the telephony circuitry 303 transforms an audio signal received by wireless receiver 204 of the STB 102 into a telephony-grade audio signal for transmission via the telephone network 122. Likewise, the telephony circuitry 303 may receive a telephony-grade audio signal from the telephone network 122 and generate an audio signal compatible with the wireless transmitter 202 of the STB 102 for transmission to a speaker 242 in the hybrid communicator/remote control 106, STB 102, or the television 104. Alternatively, or in addition, the telephony circuitry 303 may include analog or digital (e.g. DSL) modem circuitry to allow audio, video, text, and control data to be transmitted to the devices 130, 132, 140, 142, 144, 146 via the telephone network 122.

The STB 102 also preferably includes a CODEC (encoder/decoder) 304. The CODEC 304 serves to encode signals (such as audio/video signals) into a network-compatible data stream for transmission over the network 101. The CODEC 304 also serves to decode a network-compatible data stream received from the network 101. As depicted, the CODEC 304 may be implemented as a hardware component. Alternatively, or in addition, software encoding and decoding may be used. The CODEC 304 may use various algorithms, such as MPEG, Voice over IP (VoIP), and the like, for encoding and decoding audio/video data.

The STB 102 further includes a memory device 306, such as a random access memory (RAM), configured to store data for temporary use. Similarly, a read-only memory (ROM) may be provided for storing more permanent data, such as fixed code and configuration information.

In one embodiment, an audio/video (A/V) controller 308 is provided for converting decoded audio/video information into analog signals for display/playback on the television 104 or other device or devices. The A/V controller 308 may be implemented using one or more physical devices, such as separate graphics and sound devices. In alternative embodiments, the A/V controller 308 may provide a direct, digital video output for televisions 104 or other devices equipped to receive the same. Preferably, the A/V controller 308 includes graphics hardware for performing bit-block transfers (bit-blits) and other graphical operations in order to provide a graphical user interface (GUI) for display on the television 104.

In some implementations, the STB 102 may include a storage device 310, such as a hard disk drive or the like. The storage device 310 may be configured to record encoded television broadcasts and retrieve the broadcasts at a later time for decoding by the CODEC 304 and display by the A/V controller 308.

The storage device 310 may also be used in various embodiments to store viewer preferences, parental lock settings, electronic programming guide (EPG) data, programming preferences, passwords, e-mail messages, and the like. In one implementation, the storage device 310 also stores an operating system (OS) for the STB 102, such as Windows CE® or Linux®.

A CPU 312 controls the operation of the STB 102, including the other components thereof, which are coupled to the CPU 312 via a bus 314. The CPU 312 may be embodied as a microprocessor, a microcontroller, a digital signal processor (DSP) or other device known in the art. As noted above, the CPU 312 may perform logical and arithmetic operations based upon control signals generated by the hybrid communicator/remote control 106 and transmitted to the receiver 204. Alternatively, the CPU 312 may respond to control signals received through the network interface 302.

As noted above, the STB 102 may include, in certain embodiments, a microphone 244, speaker 242, and/or video camera (not shown) for capturing and reproducing audio and/or video signals. These components may be included in lieu of or in addition to similar components in the hybrid communicator/remote control 106, and/or television 104.

Of course, FIG. 3 illustrates only one possible configuration of an STB 102. Those skilled in the art will recognize that various other architectures and components may be provided within the scope of the invention. In addition, various standard components of typical STB 102 are not illustrated in order to avoid obscuring aspects of the invention.

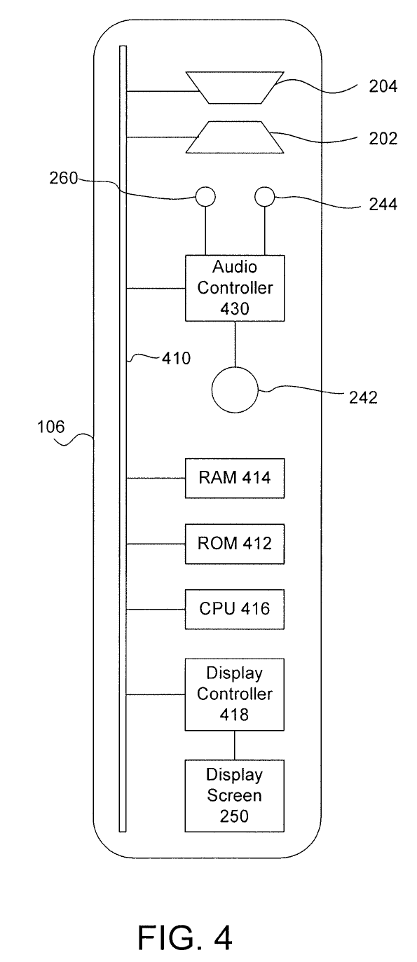

Referring to FIG. 4, a schematic block diagram illustrates physical components of a hybrid communicator/remote control 106 according to an embodiment of the invention. The hybrid communicator/remote control 106 may include a bus 410 configured to transfer digital signals between the various components of the hybrid communicator/remote control 106.

The hybrid communicator/remote control 106 may also include a read-only memory (ROM) 412 that contains data to be permanently stored within the hybrid communicator/remote control 106. For example, the ROM 412 may contain an operating system (OS) to control the operation of the hybrid communicator/remote control 106. The OS may be of a commonly available type, such as Windows CE® or Linux®. The ROM 412 may take the form of one or more programmable read-only memory (PROM) modules, electrically-erasable PROM (EEPROM) modules, or the like.

Additionally, the hybrid communicator/remote control 106 preferably includes a random access memory (RAM) 414 for storing temporary data. The RAM 414 may store, for example, the contact list 252, user preferences, calling histories, visual identifiers, and/or verbal identifiers, as described more fully hereafter.

Additionally, a CPU 416 may be provided to process instructions necessary for operation of the hybrid communicator/remote control 106. The CPU 416 may be of any known type, such as a standard microprocessor, reduced instruction set computing (RISC) processor, field programmable gate array (FPGA), or application-specific integrated circuit (ASIC). The CPU performs 416 various logical and arithmetic operations based on instructions stored in the RAM 414 and ROM 412.

A display controller 418 may be provided to control the operation of the display screen 250. As such, the display controller 418 may includes graphics hardware capable of transforming a display signal into a signal usable by the display screen 250 to produce visual output. The display controller 418 may be adapted to provide a monochromatic or color picture, as desired.

An audio controller 430 is preferably connected to the microphone 244, the speaker 242, and, optionally, the headset jack 260. The audio controller 430 may include an analog-to-digital converter (ADC), a digital-to-analog converter (DAC), compression-decompression hardware, or any other circuitry needed receive and send audio signals via the microphone 244, speaker 242, and headset jack 260.

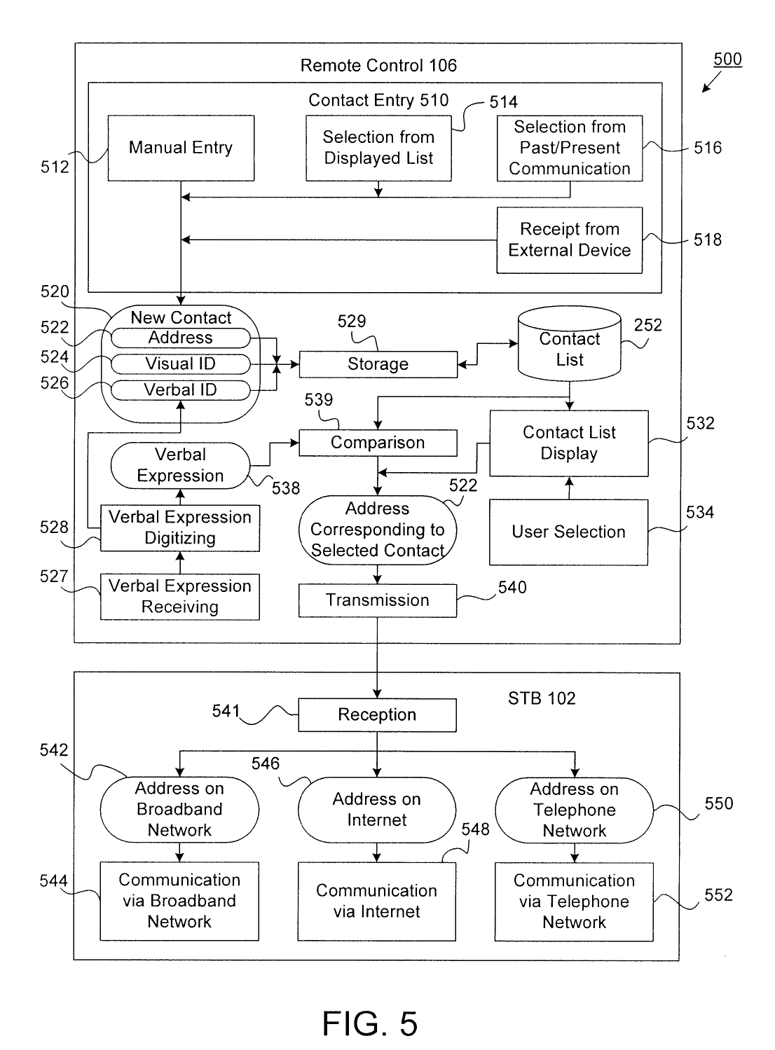

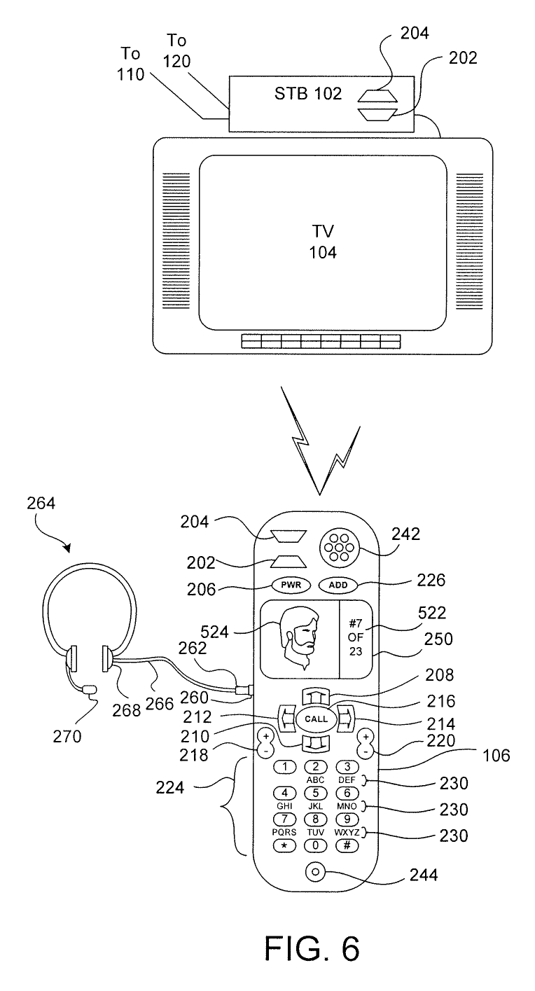

The user controls 206, 208, 210, 212, 214, 216, 218, 220, 224, and 226 have been omitted from FIG. 4 for clarity, but can be utilized to control the operation of the various components of the hybrid communicator/remote control 106. Other components, such as a power supply, additional user controls, and the like may also be included, as known in to those skilled in the art. Operation of the various components of the hybrid communicator/remote control 106 and the set top box 102 will be described in greater detail in relation to FIGS. 5 and 6.

FIG. 5 illustrates logical components of system 500 for providing a contact list 252 for a hybrid communicator/remote control 106. The depicted logical components may be implemented using one or more of the physical components shown in FIG. 3 and FIG. 4. Thus, while certain components may be depicted within the hybrid communicator/remote control 106, similar components may be embodied within the STB 102 in other embodiments. Likewise, components illustrated within the STB 102 may be embodied, in certain embodiments, within the hybrid communicator/remote control 106. Additionally, various logical components may be implemented as software or firmware.

In one implementation, the system 500 includes a contact entry component 510 configured to permit a user to enter new contacts into the contact list 252. Preferably, the contact entry component 510 provides various different mechanisms for contact entry.

For example, the contact entry component 510 may include a manual entry component 512 configured to permit the user to directly input information for a new contact into the list 252. As described previously, the user may utilize the alphanumeric buttons 224 of the hybrid communicator/remote control 106, with reference to the alphabet characters 230, to enter numbers or letters forming a name, address, and the like, for each new contact. In one embodiment, the user may activate the manual entry component 512 by pressing the “Add” button 226.

The contact entry component 510 may also include a displayed list selection component 514 configured to permit the user to select a new contact from a directory or contact list being displayed by the television 104 or the display screen 250 of the remote control 206. For example, the television 104 may display an online telephone directory, a technical support listing, an advertisement, a contact list, or the like, retrieved from the broadband communication network 101, a computer, or hand-held device. The user may then choose a contact from the displayed list and press the “Add” button 226 in order to add the selected contact to the contact list 252.

Additionally, the contact entry component 510 may include a past/present communication selection component 516 configured to permit a user to select a contact from a prior or present communication for entry into the contact list 252. For example, a history of recent calls may be displayed on the television 104 or the display screen 250 to show contacts with whom the user has communicated (or is presently communicating) over the interactive television system 200. A user may then select the desired contact from the list and press the “Add” button 226 to store information for the contact in the contact list 252.

Furthermore, the contact entry component 510 may include an external receipt component 518 configured to permit the user to receive one or more new contacts from an external device, such as a PDA, laptop computer, desktop computer, cellular phone, or another hybrid communicator/remote control 106. The hybrid communicator/remote control 106 may be configured to establish a communication channel with such devices using, for example, a wireless transmission method. A user may then select a desired contact stored in the external electronic device, for example, by highlighting the desired contact and pressing the “Add” button 226, to initiate a transfer of information related to the new contact to the hybrid communicator/remote control 106.

Ultimately, the operation of the contact entry component 510 results in the addition of a new contact 520 to the contact list 252. As illustrated, a contact 520 preferably includes an address 522. The address 522 may be a network location for another interactive television system 200 connected to the broadband communication network 101, an IP or MAC address for a device available over the Internet 112, such as the devices 150, 152 of FIG. 1, or a conventional telephone number for a wired or wireless device available over the telephone network 122, such as the devices 130, 132, 140, 142, 144, 146.

The address 522 need not correspond to a device with hardware capable of reproducing telephonic sound. For example, any of the devices 132, 140, 142, 144, 146, 152 with a display screen may be configured to communicate with the contact via e-mail or interactive text-chat (e.g., instant messaging). In certain embodiments, the interactive television system 200 or a computer within the broadband communication network 101 may be configured to convert verbal messages from the hybrid communicator/remote control 106 to text messages using standard techniques, and route the text messages to the device 132, 140, 142, 144, 146, or 152 with the associated address 522.

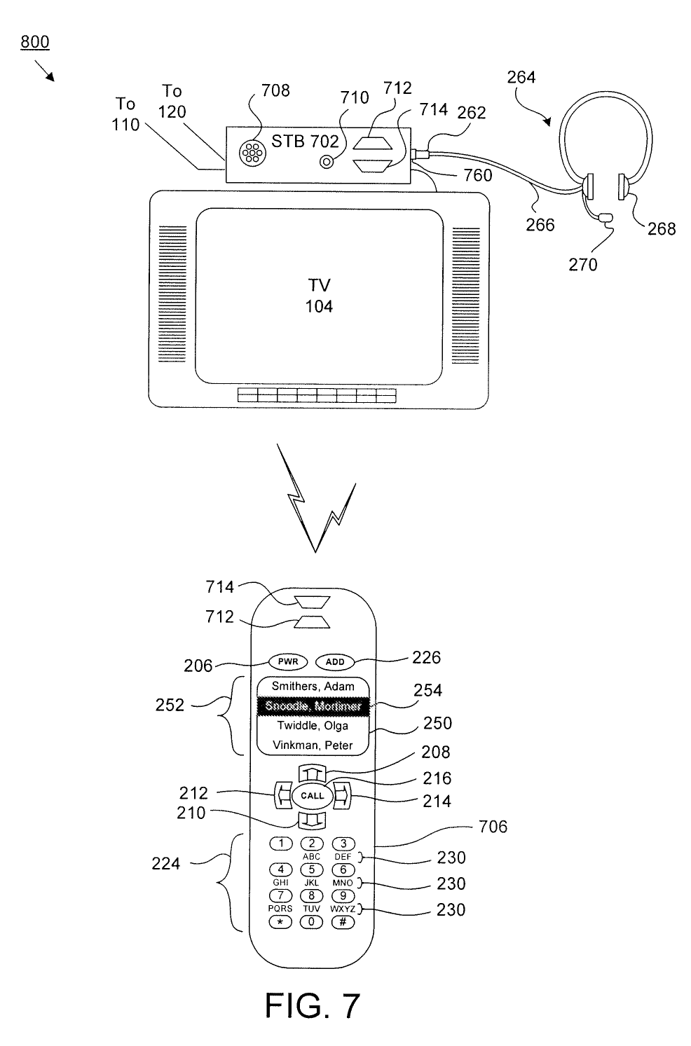

In one embodiment, a contact 520 within the list 252 also includes a visual identifier 524. As mentioned above, a visual identifier 524 is a visual representation of the identity of the contact. For example, a visual identifier 524 may be embodied as a contact's name or picture (as described more fully in relation to FIG. 7). The visual identifier 524 may also take the form of a symbol or icon (not shown) for identifying the contact, e.g., an iconic dollar sign may correspond to the user's stock broker or banker.

In one embodiment, a contact 520 within the list 252 may include an verbal identifier 526. The verbal identifier 526 may include, for example, a digital audio sample of the contact's spoken name. As described below, the verbal identifier 526 may be used to allow a user to verbally select a contact 520 from the list 252. Alternatively, or in addition, the verbal identifier 526 may be reproduced by the speaker 242 when the corresponding contact 520 is selected or highlighted by a user. This may allow, for example, a visually impaired individual to easily select a contact 520 from the list 252.

The verbal identifier 526 may be received by the hybrid communicator/remote control 106 using the components 514, 516, 518 described above. In the alternative, the verbal identifier 526 may be obtained from the user via a verbal expression receiving component 527. The verbal expression receiving component 527 may be configured to receive a verbal expression, for example, through the microphone 244.

After the verbal identifier 526 has been received, it may be digitized and associated with the contact 520. A verbal expression digitizing component 528 may be configured to receive and digitize a verbal expression 538 using conventional digitization and compression techniques.

The verbal identifier 526, along with the address 522, visual identifier 524, and any other data relating to the new contact 520, may then be stored by a storage component 529 in the contact list 252. Various data structures may be used, such as an array, linked list, or other suitable data structure within the RAM 414 or other memory device.

As previously noted, the user may select a contact to call from the contact list 252 displayed on the display screen 250. Thus, the hybrid communicator/remote control 106 may be equipped with a display component 532 configured to format and display the contact list 252 (or portion thereof on the display screen 250. Preferably, the display component 532 may also be configured to permit a user to easily change which portion of the contact list 252 is displayed, if the contact list 252 is longer than can be conveniently displayed on the display screen 250.

In one embodiment, a user selection component 534 allows the user to select a contact 520 from the contact list 252 using the buttons 208, 210, 212, 214, 216, 230 shown in FIG. 2. Once the user has selected a contact 520, the address 522 corresponding to the selected contact is preferably obtained from the contact list 252.

As previously noted, the user, in one embodiment, may also select a contact verbally, if a verbal identifier 526 is available for that contact 520. More specifically, the verbal expression receiving component 527 and verbal expression digitizing component 528 may be activated to receive a verbal expression 538 from the user.

The verbal expression 538 may be compared, through the use of a comparison component 539, with a verbal identifier 526 for each contact 520 stored in the contact list 252. The comparison component 539 may be configured, for example, to compare the wavelength, amplitude, tonal patterns, or other aspects of digitized sounds to determine whether the verbal expression 538 matches any of the verbal identifiers 526 within an acceptable degree of tolerance. If one of the verbal identifiers 526 matches the digitized verbal expression 538, the comparison component 539 may designate the contact 520 with the matching verbal identifier 526 as the selected contact 520 and retrieve the corresponding address 522.

The retrieved address 522 may be transmitted by a transmission component 540 to a reception component 541 within the STB 102 or another device that performs the function (e.g., an advanced television or the like, as noted previously). After the address 522 is received, a two-way communication channel may be established in different ways, depending on what type of address was received. For example, if the address 522 corresponds to an address 542 on the broadband communication network 101, i.e., an interactive television system operated by another user, the STB 102 may take the steps necessary to initiate communication via the broadband communication network 101 through the use of a broadband network communication component 544.

For example, the broadband communication component 544 may be configured to route the communication to the broadband communication network through one of the head-ends 110, to the broadband communication network 101, and then to an STB 102 of another interactive television system through the same head-end 110 or a different head-end 110, if the communicating parties do not use the same head-end 110. The CO 120, the telephone network 122, and the Internet 112 need not be involved in the communication.

If, however, the address 522 comprises an Internet address 546, such as an IP or MAC address, an Internet communication component 548 may be engaged to route the communication appropriately. The Internet communication component 548 may route the communication to an Internet-accessible device, such as the devices 150, 152 depicted in FIG. 1, through the head-end 110, the broadband communication network 101, and the Internet 112. The Internet 112 may then route the communication appropriately through the use of its own internal protocols. Communication with Internet-accessible devices may also be routed through the CO 120 for the telephone network 122.

If the address 522 comprises an address 550 on the telephone network 122, i.e., a telephone number or the like, a telephone network communication component 552 may route the communication appropriately. The STB 102 may communicate with a device connected to the telephone network 122 by a wired or wireless connection, such as the devices 130, 132, 140, 142, 144, 146 by transmitting the communication directly from the STB 102 to the CO 120, and from the CO 120 to the telephone network 122. The telephone network 122, by its own internal processes, then routes the communication to the appropriate device.

In alternative embodiments, the STB 102 may be configured to route all communication, regardless of the nature of the address 522, to a head-end 110 or other intermediate node of the broadband communication network 101. Preferably, the head-end 110 or the other intermediate network node includes the communication components 544, 548, 552 necessary to ensure proper routing of the communication.

FIG. 6 illustrates an alternative configuration of a displayed contact list 252 in which a visual identifier 524 of a contact 520 is a picture rather than name. The pictures may be digital photographs, drawings, or even icons associated with the contact. For example, the RAM 414 or the ROM 412 may contain a plurality of unassociated icons that the user can select to assign to certain contacts.

The display screen 250 may be configured to show only one of the picture-based visual identifiers 524 at a time or may show several simultaneously. The visual identifiers 524 may be arranged in alphabetical order of the contact's name, in chronological order of date/time of entry into the contact list 520, or may be arranged in a user-specified order. As depicted, the contact list 252 may display an indication of the relative position of the visual indicator 524 within the list 252.

As with the embodiment of FIG. 2, the television 104 may work in conjunction with, or in some cases, instead of, the display screen 250 to provide the operation of the contact list 252. For example, the television 104 could be configured to show the pictures 752. If the pictures 752 are shown on the display screen 250, the screen 250 may advantageously be a color liquid crystal display (color LCD).

Referring to FIG. 7, there is shown an alternative interactive television system 700 according to an embodiment of the invention. The interactive television system 700 may include an STB 702 configured to receive and process audio/video communication and a remote control 706 configured to permit selection of contacts from the contact list 252.

More specifically, the STB 702 may include a built-in speaker 708 and microphone 710. The speaker 708 and microphone 710 may be configured somewhat differently than the speaker and microphone 242, 244 of FIG. 2, in that they may be specially designed to project and receive sound over greater distances with a comparatively small amount of interference and feedback. Thus, rather than talking into the remote control device, the user may simply talk from a location close enough to the STB 702 for the microphone 710 to capture the user's voice clearly.

The STB 702 and the remote control 706 may also have wireless transmitters 712 and wireless receivers 714, which may be configured somewhat differently than the transmitters 202 and receivers 204 of FIG. 2. More specifically, the wireless transmitters 712 and the wireless receivers 714 of FIG. 7 need not transmit or receive a continuous audio/video stream, and may therefore be more simply constructed than the wireless transmitters 202 and the wireless receiver 204. For example, the wireless transmitter 712 and/or the wireless receiver 714 may be configured to use infrared (IR) frequencies.

In addition or alternative to the speaker 708 and the microphone 710, the STB 702 may include a headset jack 760 configured to receive a plug 262 connected to a headset 264, as previously described in connection with FIG. 2.

The remote control 706 thus need not include a speaker and microphone, but may otherwise be configured in the same fashion as the hybrid communicator/remote control 106. The remote control 106 allows a user to select a contact from the contact list 252, after which a two-way communication channel may be established. If desired, the remote control 706 may have a microphone (not shown) to permit vocal selection of a contact from the contact list.

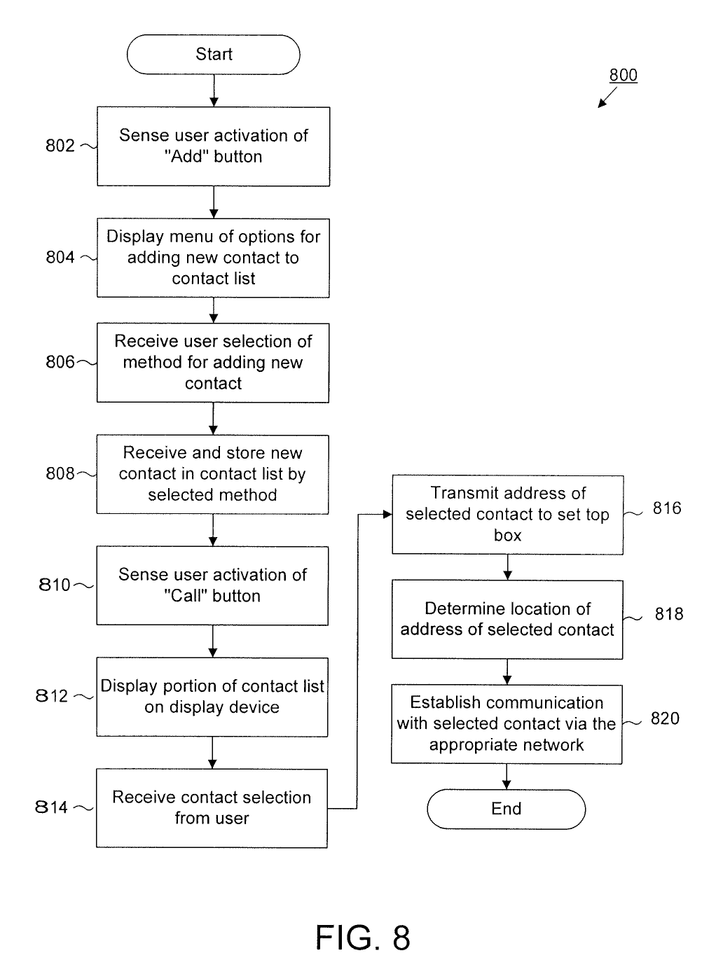

Referring to FIG. 8, there is shown a flowchart of one possible method 800 of operation of the invention. Initially, the hybrid communicator/remote control 106 may sense 802 user activation of the “Add” button 226. Thereafter, a list of menu options for adding new contacts to the list may be displayed 804. The menu options may correspond with the various components 512, 514, 516, 518 of the contact entry component 510. For example, the display screen 250 may display text to query whether the user wishes to add the new contact by manual entry, selection from a displayed list, selection from past or present communication, or receipt from an external device.

The hybrid communicator/remote control 106 may then receive 806 a user selection of a method for adding the new contact. The selection may be made through the use of one or more of the user controls 208, 210, 212, 214, 216, 230. After the selection has been received 806, the hybrid communicator/remote control 106 may receive and store 808 the data 522, 524, 526 pertaining to the contact in the contact list 252.

When a contact list 252 has been formed, the user can employ the contact list 252 to initiate communication with a contact, for example, by highlighting a desired contact and pressing the “Call” button 216. The hybrid communicator/remote control 106 may sense 810 user activation of the “Call” button and display 812 a portion of the contact list 252 on the display screen 250. Thereafter, the hybrid communicator/remote control 106 receives 814 the user selection of the contact.

Next, the address 522 corresponding to the user selection may be transmitted 816 to the STB 102 to initiate the communication. The STB 102, or some suitable equivalent, may determine 818 the location of the address 522, i.e., whether the address 522 comprises an address 542 on the broadband communication network 101, an address 522 on the Internet 112, or an address 550 on the telephone network 122. The STB 102 may then establish 820 a communication channel with the selected contact via the appropriate network, i.e., the broadband communication network 101, the Internet 112, or the telephone network 122.

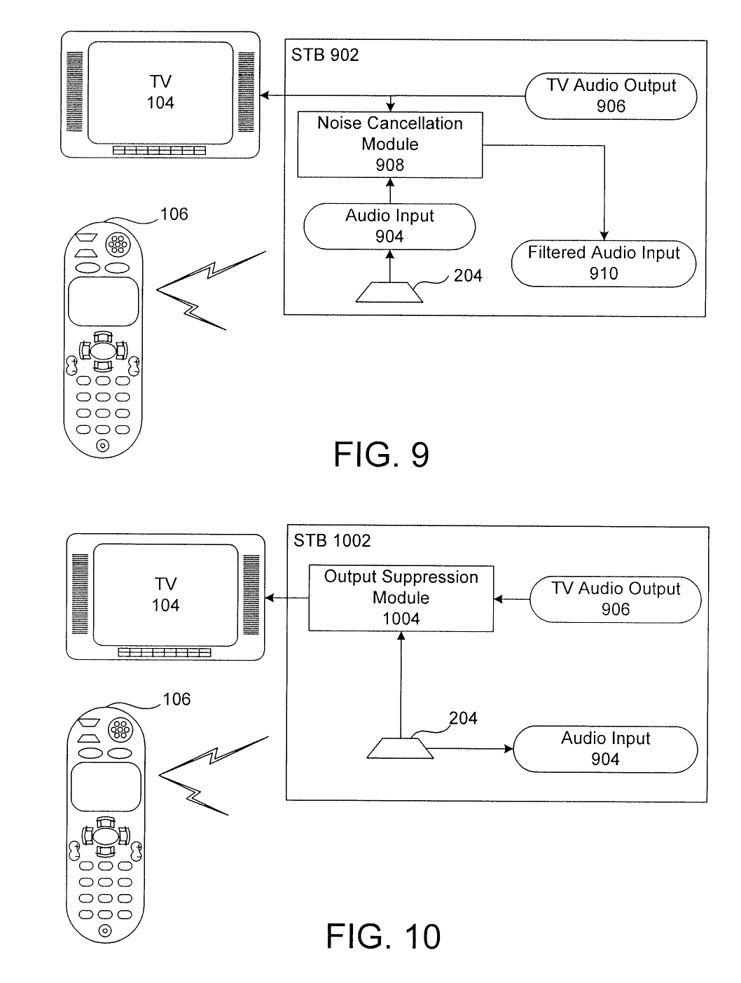

Referring to FIG. 9, there is shown an alternative STB 902 according to an embodiment of the invention. In many cases, a hybrid communicator/remote control 106 may be used in close proximity to a television 104 while capturing audio input 904 (e.g., during communication with another party). Thus, TV audio output 906 from the television 104 may be captured with the user's voice by the hybrid communicator/remote control 106, interfering with communication.

In one configuration, the STB 902 may include a noise cancellation module 908 to cancel unwanted noise (e.g., the TV audio output 906, the other party's voice, environmental sounds, etc.) from the audio input 904 and produce filtered audio input 910. The filtered audio input 910 includes the user's voice with the other background noise (including the TV audio output 906) being cancelled or substantially cancelled. The filtered audio input 908 may then be transmitted to the other party during the course of two-way communication.

In one embodiment, the audio input 104 may be encoded by a CODEC 304 (see FIG. 3) into a digital signal and provided to the noise cancellation module 904. Likewise, the TV audio output 906 may be encoded by the CODEC 304 and provided to the noise cancellation module 904. Alternatively, the TV audio output 906 may be provided in digital form by the A/V controller 308 (see FIG. 3). By providing the TV audio output 906, the noise cancellation module 904 knows what signal to remove from the audio input 904.

Those skilled in the art will appreciate that there are many systems and methods that may be used to cancel noise (e.g., the TV audio output 906) from the audio input 904. For example, an adaptive filter may be implemented in software and executed on the CPU 312. It will be appreciated that other combinations of hardware and/or software may also be used to accomplish for the same purpose. For example, a digital signal processor (not shown) may be included within the STB 902 for noise cancellation. In addition, analog systems and techniques may be used to achieve noise cancellation. In still other embodiments, a noise cancellation module 908 may be implemented within the hybrid communicator/remote control 106.

In one embodiment, standard training techniques may be used by the noise cancellation module 908 to estimate the noise path and improve noise cancellation. A noise generator (not shown) within the STB 902 may generate white noise to be played by the TV 104 and received by the microphone of the hybrid communicator/remote control 106. The noise cancellation module 908 may use the white noise captured by the hybrid communicator/remote control 106 to modify the adaptive filter to improve the noise cancellation.

In some cases, retraining may be required. Depending upon the difference between the acoustics of different rooms, or the position of the user in the room, the noise cancellation module 908 may need to be retrained for the new room or position. Retraining may be automatic or user-initiated.

Of course, it will be appreciated that the normal TV audio output 906 being sent through the TV 104 may also be used for training. An embodiment of the noise cancellation module 908 may be designed to continually train and adapt to estimate the noise received by the microphone of the hybrid communicator/remote control 106.

Referring to FIG. 10, there is shown yet another alternative STB 1002 including an output suppression module 1004. The output suppression module 1004 may be used to suppress the TV audio output 1004 when audio input 904 is received by the STB 1002, e.g. via the wireless receiver 204 during two-way communication. When audio input 904 is detected, the module 1004 effectively mutes the TV 104 to reduce interference with capturing audio input 904. The TV audio output 906 may be resumed once capture of the audio input 904 is terminated, e.g., after the communication is completed. Various standard circuits may be used to reduce the volume of, or terminate, the TV audio output 1004, which are well known to those skilled in the art.

The output suppression module 1000 may be coupled to the wireless receiver 204 and/or the CPU 312 (not shown) in order to determine whether audio input 904 is being received by the hybrid communicator/remote control 106. For example, when an two-way audio connection is established, the CPU 312 may signal the output suppression module 1004 to suppress the TV audio output 906. Alternatively, the wireless receiver 204 may provide a signal to the output suppression module 1004 when audio input 904 is being received. In certain embodiments, the output suppression module 1000 may calculate averages over time of the audio input 904 to detect when audio input 904 is being received.

Based on the foregoing, the present invention offers numerous advantages not available in conventional approaches. For example, the present invention allows the user to easily gather and store contact information for contacts in the hybrid communicator/remote control. The contacts may be accessible through devices connected to different networks, including a broadband communication network, a telephone network, and the Internet 112. The contacts may be easily entered into the hybrid communicator/remote control 106 in a variety of ways, including manual entry and selection from a stored directory or list.

Furthermore, a user may place a call to any of the contacts by simply choosing a visual identifier representing the contact from a portion of the contact list displayed on the display screen. The visual identifier may include text, pictures, icons, or the like. In the alternative, the user may simply speak into the hybrid communicator/remote control to provide a verbal expression that the hybrid communicator/remote control can correlate with a selected contact. In either case, the user can place a call easily from the vicinity of the television, without having to retrieve a telephone or look up the telephone number of a party he or she wishes to contact.

While specific embodiments and applications of the present invention have been illustrated and described, it is to be understood that the invention is not limited to the precise configuration and components disclosed herein. Various modifications, changes, and variations which will be apparent to those skilled in the art may be made in the arrangement, operation, and details of the methods and systems of the present invention disclosed herein without departing from the spirit and scope of the invention.

What is claimed is:

1. A remote control for an interactive television system, the remote control comprising:
a memory configured to store a list of contacts, each contact having an associated address for establishing communication with the contact via the interactive television system;
a display device configured to display at least a portion of the list of contacts;
a plurality of user controls configured to receive a user selection of a contact from the list, the user controls further being configured to remotely operate the interactive television system; and
a wireless transmitter configured to transmit the address corresponding to the selected contact to the interactive television system to initiate communication between a user and the selected contact.

2. The remote control of claim 1, wherein the display device comprises a liquid crystal display (LCD).

3. The remote control of claim 1, further comprising:
a microphone configured to capture a first audio signal for transmission to the interactive television system via the wireless transmitter.

4. The remote control of claim 3, further comprising:
a wireless receiver configured to receive a second audio signal; and
a speaker configured to generate audible output from the second audio signal.

5. The remote control of claim 4, wherein the speaker and the microphone are further configured to operate simultaneously to provide two-way audio communication with the contact via the interactive television system.

6. The remote control of claim 5, wherein at least one address comprises a network address.

7. The remote control of claim 6, wherein the network address is selected from the group consisting of an Internet Protocol (IP) address, a telephone address, and a Media Access Control (MAC) address.

8. The remote control of claim 7, wherein the network address designates a second interactive television system.

9. The remote control of claim 3, further comprising:
a storage component configured to store at least one digitized verbal identifier for at least one contact of the list of contacts; and
a voice recognition component configured to receive and digitize a verbal expression from the user, to compare the digitized verbal expression with the digitized verbal identifier, and to designate the contact with a digitized verbal identifier that matches the digitized verbal expression as the selected contact.

10. The remote control of claim 1, further comprising:
a contact entry component configured to receive a user selection of a new contact to be entered into the list of contacts.

11. The remote control of claim 10, wherein the user controls are further configured to enter a new contact into the list of contacts stored in the memory.

12. The remote control of claim 11, wherein the user controls are further configured to manually enter the new contact.

13. The remote control of claim 11, wherein the user controls are further configured to select a contact from a list being displayed by the interactive television system as the new contact.

14. The remote control of claim 11, wherein at least one user control is configured to select a contact from a list of contacts with whom the user has previously communicated.

15. The remote control of claim 11, wherein the user controls are further configured to receive the new contact from list stored in an external electronic device.

16. The remote control of claim 1, wherein the memory is further configured to store a visual identifier associated with each contact, the visual identifier being viewable by a user to identify an associated contact, wherein the display device is further configured to display the visual identifier.

17. The remote control of claim 16, wherein the identifiers comprises a plurality of characters forming a name of the contact.

18. The remote control of claim 16, wherein the visual identifier comprise a picture of the contact.

19. The remote control of claim 16, wherein the visual identifiers comprises an iconic symbol.

20. A system for providing two-way communication using an interactive television system, the system comprising:
a remote control configured to control operation of the interactive television system, the remote control further comprising a plurality of user controls configured to receive a user selection of a contact from a list of contacts, each contact having an associated address for establishing two-way communication with the contact, the remote control further comprising a wireless transmitter configured to transmit the address corresponding to the selected contact; and
a set top box having a wireless receiver for receiving the address corresponding to the selected contact from the remote control, the set top box being further configured to establish two-way communication with the selected contact via the interactive television system.

21. The system of claim 20, wherein the remote control further comprises:
a microphone configured to capture a first audio signal for transmission to the set top box via the wireless transmitter;
a wireless receiver configured to receive a second audio signal; and
a speaker configured to generate audible output from the second audio signal.

22. The system of claim 21, wherein the speaker and the microphone are further configured to operate simultaneously to provide two-way audio communication with the contact via the interactive television system.

23. The system of claim 20, wherein the remote control further comprises a memory configured to store the list of contacts.

24. The system of claim 23, wherein the remote control further comprises a display device configured to display at least a portion of the list of contacts.

25. The system of claim 20, wherein the set top box further comprises:
a microphone configured to capture a first audio signal for transmission to the set top box via the wireless transmitter; and
a speaker configured to generate audible output from the second audio signal.

26. The system of claim 25, wherein the speaker and the microphone are further configured to operate simultaneously to provide two-way audio communication with the contact via the interactive television system, through the set top box.

27. The system of claim 26, wherein the set top box further comprises a memory configured to store the list of contacts.

28. The system of claim 27, wherein the contacts are displayed on a television of the interactive television system.

29. A system for providing two-way communication using an interactive television system, the system comprising:
a remote control configured to control operation of the interactive television system, the remote control comprising a storage component configured to store a list of contacts, each contact having an associated address for establishing communication with the contract via the interactive television system; a display component configured to display at least a portion of the list of contacts; a user selection component configured to receive a user selection of a contact from the list; and a transmission component configured to transmit the address corresponding to the selected contact to the interactive television system to initiate communication between a user and the selected contact.

30. The system of claim 29, further comprising:
a contact entry component configured to receive user selections of new contacts to be entered into the list of contacts.

31. The system of claim 30, wherein the contact entry component further comprises a manual entry component configured to receive a new contact manually entered by the user.

32. The system of claim 30, wherein the contact entry component further comprises a displayed list selection component configured to receive a new contact from a list displayed by the interactive television system.

33. The system of claim 30, wherein the contact entry component further comprises a past/present communication selection component configured to receive a new contact selected from the group consisting of a contact with whom communication is presently occurring over the interactive television system and a contact with whom communication has previously occurred over the interactive television system.

34. The system of claim 30, wherein the contact entry component further comprises an external receipt component configured to receive a new contact from an external electronic device.

35. The system of claim 30, further comprising:
a set top box configured to receive the address corresponding to the selected contact from the remote control and to initiate communication between the user and the selected contact.

36. The system of claim 35, wherein the set top box comprises a broadband communication component configured to initiate communication with the selected contact via a second interactive television system.

37. The system of claim 35, wherein the set top box comprises an Internet communication component configured to initiate communication with the selected contact via the Internet.

38. The system of claim 35, wherein the set top box comprises a telephone network component configured to initiate communication with the selected contact via a telephone network.

39. The system of claim 35, wherein the interactive television system comprises an output device for generating audible output, wherein the remote control comprises an input device for capturing an audio signal including the audible output, and wherein the set top box comprises a noise cancellation component configured to cancel the audible output from captured audio signal.

40. The system of claim 35, wherein the interactive television system comprises an output device for generating audible output, wherein the remote control comprises an input device for capturing an audio signal, and wherein the set top box comprises an output suppression component configured to suppress the audible output when the input device is capturing an audio signal.

41. A method of providing two-way communication over an interactive television system, the interactive television system including a remote control configured to control operation of the interactive television system, the remote control having a memory, a display device, a plurality of user controls, and a wireless transmitter, the method comprising:
storing a list of contacts in the memory, each contact of the list of contacts having an associated address for establishing communication with the contact via the interactive television system;
displaying at least a portion of the contacts of the list of contacts on the display device;
receiving a user selection of a contact from the list; and
transmitting the address associated with the selected contact to the interactive television system to initiate communication between the user and the selected contact.

42. The method of claim 41, further comprising:
utilizing the remote control to capture audible input and generate audible output to provide two-way communication via the interactive television system through the remote control.

43. The method of claim 41, wherein at least one address comprises a network address.

44. The method of claim 43, wherein the network address is selected from the group consisting Internet Protocol (IP) addresses, telephone addresses, and Media Access Control (MAC) addresses.

45. The method of claim 43, wherein the network address designates a second interactive television system.

46. The method of claim 41, wherein receiving a user selection of a contact comprises:
receiving a verbal expression from the user;
digitizing the verbal expression;
comparing the digitized verbal expression to a plurality of digitized verbal identifiers contained in the memory, each digitized verbal identifier corresponding to a contact of the list of contacts; and
designating a contact with a digitized verbal identifier that matches the digitized verbal expression as the selected contact.

47. The method of claim 41, wherein receiving a user selection of a contact comprises:
receiving a selection from the user via the user controls to designate the selected contact.

48. The method of claim 41, further comprising:
receiving at least one selection of a new contact from the user to form a list of contacts.

49. The method of claim 48, wherein receiving at least one selection of a new contact from the user comprises:
receiving a new contact manually through the user controls.

50. The method of claim 48, wherein receiving at least one selection of a new contact from the user comprises:
receiving a selection of a contact from a list being displayed by the interactive television system.

51. The method of claim 48, wherein receiving at least one selection of a new contact from the user comprises:
receiving a selection of a contact selected from the group consisting of a contact with whom communication is presently occurring over the interactive television system, and a contact with whom communication has previously occurred over the interactive television system.

52. The method of claim 48, wherein receiving selections of new contacts from the user comprises:
receiving a new contact from a list stored in an external electronic device.

53. The method of claim 41, wherein each contact of the list of contacts further has an associated visual identifier viewable by a user to identify an associated contact, and wherein displaying at least a portion of the list of contacts on the display device further comprises displaying at least a portion of the visual identifiers.

54. The method of claim 53, wherein at least one visual identifier comprises a plurality of characters forming a name of the contact with which the visual identifier is associated.

55. The method of claim 53, wherein at least one visual identifier comprises a picture of the contact.

56. The method of claim 53, wherein at least one visual identifier comprises an iconic symbol.

57. The method of claim 41, wherein the interactive television system comprises an output device for generating audible output, wherein the remote control comprises an input device for capturing an audio signal including the audible output, the method further comprising:
canceling the audible output from captured audio signal.

58. The method of claim 41, wherein the interactive television system comprises an output device for generating audible output, wherein the remote control comprises an input device for capturing an audio signal, the method further comprising:
suppressing the audible output when the input device is capturing an audio signal.

59. A method of providing two-way communication over an interactive television system, the interactive television system including a remote control configured to control operation of the interactive television system, the remote control having a memory, a display device, a plurality of user controls, a wireless transmitter, a wireless receiver, a microphone, and a speaker, the method comprising:
storing a list of contacts in the memory, each contact of the list of contacts having an associated address for establishing communication with the contact via the interactive television system;
displaying at least a portion of the contacts of the list of contacts on the display device;
detecting a user selection of a contact from the list; and
transmitting the address associated with the selected contact to the interactive television system;
establishing a two-way communication channel between the user and the selected contact using the interactive television system;
capturing audio input via the microphone in the remote control;
transmitting the audio input to the interactive television system via the wireless transmitter;
receiving audio output from the interactive television system via the wireless receiver; and
outputting the audio output via the speaker in the remote control.

60. A remote control for an interactive television system, the remote control comprising:
a memory configured to store a list of contacts, each contact having an associated address for establishing communication with the contact via the interactive television system;
a display device configured to display at least a portion of the list of contacts;
a plurality of user controls configured to receive a user selection of a contact from the list; and
at least one dedicated user control configured to remotely operate the interactive television system.
